(19) United States
(12) Patent Application Publication
(10) Pub. No.: US 2004/0262673 A1
(43) Pub. Date: Dec. 30, 2004

(54) Read-only memory cell and fabrication method thereof

(76) Inventors: Ching-Nan Hsiao, Kaohsiung (TW); Chao-Sung Lai, Ilan (TW); Yung-Meng Huang, Taoyuan (TW); Ying-Cheng Chuang, Taoyuan (TW)

Correspondence Address: QUINTERO LAW OFFICE, 1617 BROADWAY, 3RD FLOOR, SANTA MONICA, CA, 90404, US

(21) Appl. No.: 10/801,625

(22) Filed: Mar. 16, 2004

(30) Foreign Application Priority Data
Jun. 26, 2003 (TW) 92117375

(51) Int. Cl. H01L 21/8242

(52) U.S. Cl. 257/324

(57) ABSTRACT

A read-only memory cell (ROM) and a fabrication method thereof. The cell comprises a substrate, a plurality of bit lines, a plurality of bit line oxides, a gate dielectric layer and a word line. The bit lines are formed near the surface of the substrate. The bit line oxides are disposed over the bit lines. The gate dielectric layer is disposed over the substrate between the bit lines and further comprises a silicon-rich oxide layer. The word line is disposed over the bit line oxides and the gate dielectric layer.

### BACKGROUND OF THE INVENTION

1. Field of the Invention

The present invention relates to a read-only memory cell, and in particular to a read-only memory cell with chargeable areas disposed in a silicon-rich oxide layer.

2. Description of the Related Art

In the non-volatile memory industry, development of nitride read-only memory (NROM) began in 1996. This new non-volatile memory technology utilizes oxide-nitride-oxide (ONO) gate dielectric and known mechanisms of programming and erasing to create two separate bits per cell. Thus, the NROM bit size is half of the cell area. Since silicon die size is the main element in cost structure, it is apparent why NROM technology is considered an economical breakthrough.

FIG. 1 is a cross-section showing a conventional NROM cell structure. This cell includes a silicon substrate 100 with two separated bit lines (source and drain) 102, two bit line oxides 104 formed over each of the bit lines 102, respectively, and an ONO layer 112 having a silicon nitride layer 108 sandwiched between bottom silicon oxide layer 106 and top silicon oxide layer 110 formed on the substrate 100 between bit line oxides 102. A gate conductive layer 114 (word line) lies on top of the bit line oxides 104 and the ONO layer 112.

The silicon nitride layer 108 in the ONO structure 112 has two chargeable areas 107 and 109 adjacent to the bit lines 102. These areas 107 and 109 store charges during memory cell programming. To program the left bit near area 107, left bit line 102 acts as the drain and receives the high programming voltage. Simultaneously, right bit line 102 acts as the source and is grounded. The opposite is true for programming area 109. Moreover, each bit is read in a direction opposite its programming direction. To read the left bit, stored in area 107, left bit line 102 is the source and right bit line 102 is the drain. The opposite is true for reading the right bit, stored in area 109. In addition, the bits are erased in the same direction that they are programmed.

However, the conventional NROM stores charges in a silicon nitride layer which has a lower work function and worse data retention; thus, data stored in a conventional NROM is easily lost.

### SUMMARY OF THE INVENTION

The present invention provides a substrate, a plurality of bit lines, a plurality of bit line oxides, a gate dielectric layer and a word line. The bit lines are formed on the substrate. The bit line oxides are disposed over the bit lines. The gate dielectric layer is disposed over the substrate between the bit lines and further comprises a silicon-rich oxide layer. The word line is disposed over the bit line oxides and the gate dielectric layer.

The present invention stores charges in the silicon-rich oxide layer rather than in a silicon nitride layer. The silicon-rich oxide layer has a higher work function, thus improving data retention. Additionally, the silicon-rich oxide layer has lower crystal attenuation. The present invention provides better data retention and longer life.

### BRIEF DESCRIPTION OF THE DRAWINGS

The present invention can be more fully understood by reading the subsequent detailed description and examples with references made to the accompanying drawings, wherein:

FIG. 1 is a cross-section showing the conventional NROM cell structure;

FIGS. 2a˜2f are cross-sections showing a method for fabrication of a ROM cell of the present invention;

FIG. 3 is a cross-section showing the ROM cell of the present invention.

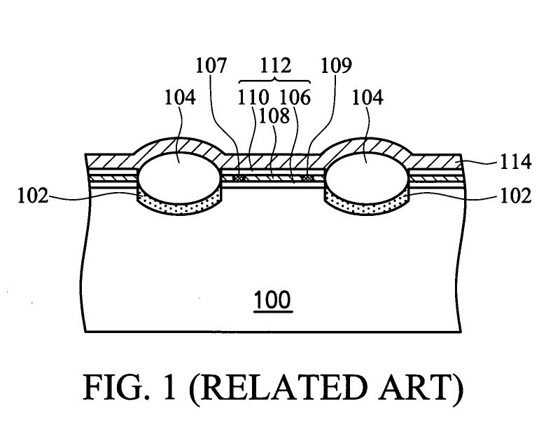

### DETAILED DESCRIPTION OF THE INVENTION

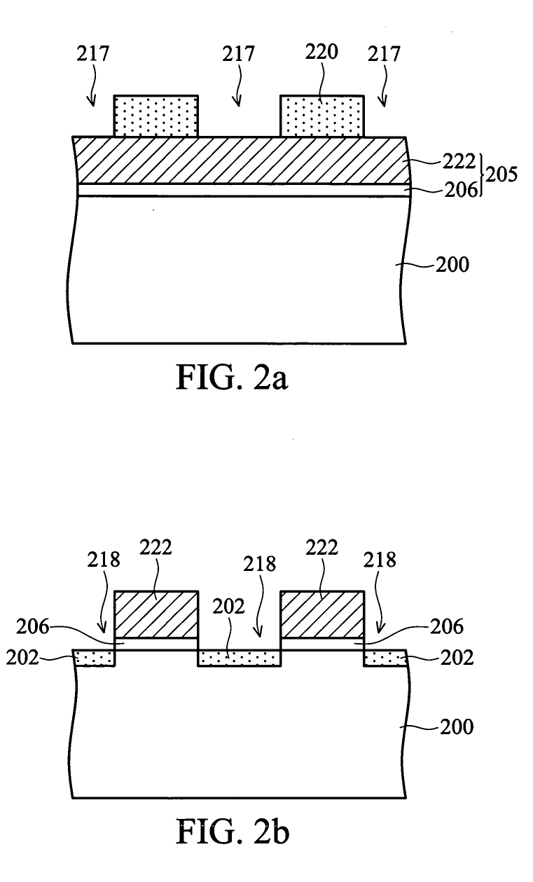

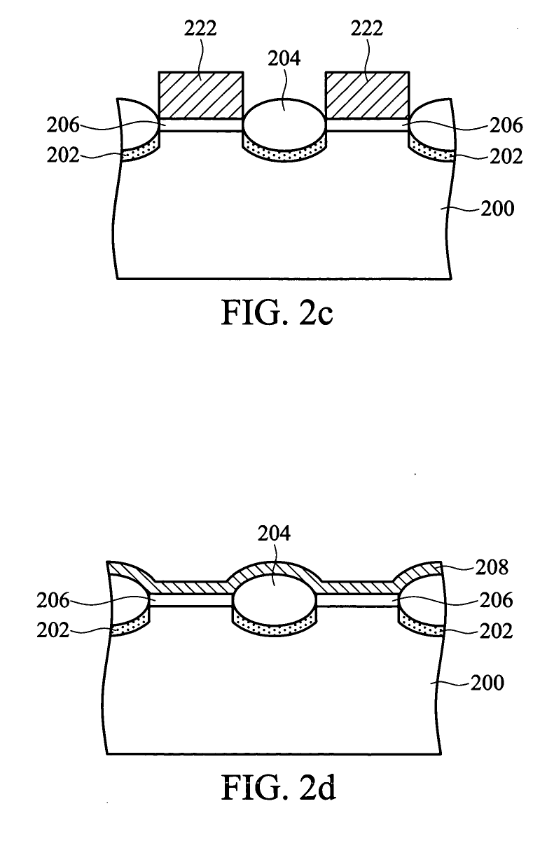

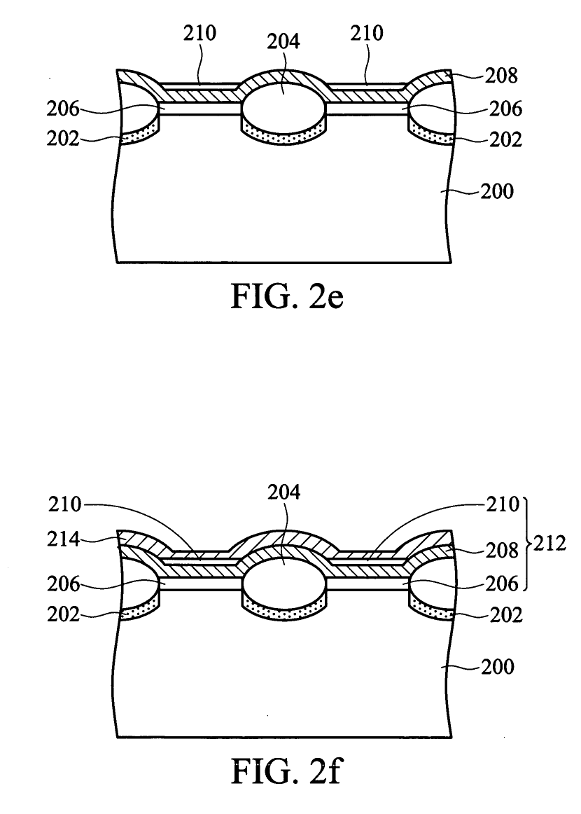

FIGS. 2a˜2f illustrate a method for fabricating a read-only memory (ROM) cell of the present invention. First, as shown in FIG. 2a, a substrate 200, such as a silicon substrate, is provided. A mask layer 205 is formed on the substrate 200. The mask layer 205 can be a single layer or a plurality of layers. As shown in FIG. 2a, the mask layer 205 is preferably composed of a first gate oxide layer 206 and a thicker silicon nitride layer 222. The first gate oxide layer 206 has a thickness about 100 Å and can be formed by thermal oxidation or conventional CVD, such as atmospheric pressure CVD (APCVD) or low pressure CVD (LPCVD). The silicon nitride layer 222 overlying the first gate oxide layer 206 has a thickness of about 1000˜2000 Å and can be formed by LPCVD using SiCl₂H₂ and NH₃ as a reaction source. Next, a photoresist layer 220 is coated on the mask layer 205. Thereafter, lithography is performed on the photoresist layer 220 to define a bit line pattern and form a plurality of bit line openings 217.

Next, in FIG. 2b, the photoresist layer 220 is used as a mask to anisotropically etch the mask layer 205, using, for example, reactive ion etching (RIE), to transfer the pattern of the photoresist layer 220 to the mask layer 205, and form bit line openings 218. Thereafter, suitable wet etching or ashing is performed to remove photoresist layer 220. Subsequently, ion implantation, with phosphorus for example, is performed on the surface of the substrate 200 in the bit line openings 218, to form doping area 202 as bit lines.

Next, in FIG. 2c, a silicon oxide film is formed by thermal oxidation on an area of the substrate 200 where is not protected by the silicon nitride layer 222 and the first gate oxide layer 206, as bit line oxides 204.

Next, in FIG. 2d, the silicon nitride layer 222 is removed by wet etching, by soaking with hot H₃PO₄ for example. Thereafter, a silicon-rich oxide layer 208 is formed on the first gate oxide layer 206 and the bit line oxides 204. The silicon-rich oxide layer 208 can be formed by plasma chemical vapor deposition under a temperature lower than 400° C., using, for example, Tetraethylor-thosilicate (TOES) as precursor to deposit PE-TEOS, or SiH₄ as precursor to deposit PE-SiH₄. By increasing the flow rate of TOES or SiH₄, the oxide layer contains more silicon element.

Next, in FIG. 2e, a second gate oxide layer 210 is formed on the surface of the silicon-rich oxide layer 208 over the first gate oxide layer 206 by chemical vapor deposition.

Finally, a conductive layer 214, such as polysilicon, is formed over the second gate oxide layer 210 and the silicon-rich oxide layer 208. Thereafter, a photoresist layer (not shown) is coated on the conductive layer 214. Lithography and etching are successively performed on the conductive layer 214, thereby defining a word line. Thus, the ROM cell according to the present invention is completed after the photoresist layer is removed.

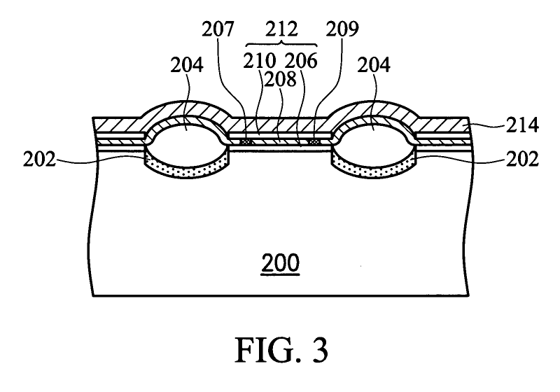

FIG. 3 shows the structure of the ROM cell of the present invention. The ROM cell comprises substrate 200, bit lines 202 (source and drain), bit line oxides 204, gate dielectric layer 212 and word line 214. The bit lines 202 are formed near the surface of substrate 200. The bit line oxides 204 are disposed over the bit lines 202. The gate dielectric layer 212 is disposed over the substrate between the bit lines 202. The word line 214 is disposed over the bit line oxides 204 and the gate dielectric layer 212. The gate dielectric layer 212 comprises a silicon-rich oxide layer 208, a first oxide layer 206 and a second oxide layer 210. The silicon-rich oxide layer 208 comprises chargeable areas 207 and 209. To program the left bit near area 207, left bit line 202 is the drain and receives the high programming voltage. Simultaneously, right bit line 202 is the source and is grounded. The opposite is true for programming area 209. Moreover, each bit is read in a direction opposite its programming direction. To read the left bit, stored in area 207, left bit line 202 is the source and right bit line 202 is the drain. The opposite is true for reading the right bit, stored in area 209. In addition, the bits are erased in the same direction that they are programmed.

The present invention stores charges in the silicon-rich oxide layer rather than in the silicon nitride layer. The silicon-rich oxide layer has a higher work function, thus improving data retention. Additionally, the silicon-rich oxide layer has lower crystal attenuation. The present invention provides better data retention and longer life.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A read-only memory cell, comprising:
a substrate;
a plurality of bit lines, formed near the surface of the substrate;
a plurality of bit line oxides, disposed over the bit lines;
a gate dielectric layer, disposed over the substrate between the bit lines, the gate dielectric layer comprising a silicon-rich oxide layer; and
a word line, disposed over the bit line oxides and the gate dielectric layer.

2. The cell as claimed in claim 1, wherein the gate dielectric layer further comprises a first gate oxide layer, disposed between the silicon-rich oxide layer and the substrate.

3. The cell as claimed in claim 1, wherein the gate dielectric layer further comprises a second gate oxide layer, disposed between the silicon-rich oxide layer and the bit lines.

4. The cell as claimed in claim 1, wherein the silicon-rich oxide layer is further disposed between the word line and the bit line oxides.

5. A method for fabricating a read-only memory cell, comprising the steps of:
providing a substrate;
forming a first gate oxide layer on the substrate;
defining a bit line pattern in the first gate oxide layer and forming a plurality of bit line openings;
forming a plurality of doping areas in the substrate near its surface in the bit line openings as bit lines;
forming a plurality of bit line oxides in the bit lines;
forming a silicon-rich oxide layer over the first gate oxide layer;
forming a second gate oxide layer on the silicon-rich oxide layer; and
forming a conductive layer over the second gate oxide layer and the bit line oxides.

6. The method as claimed in claim 5, wherein the first gate oxide layer is formed by thermal oxidation.

7. The method as claimed in claim 5, wherein the first gate oxide layer is formed by chemical vapor deposition.

8. The method as claimed in claim 5, wherein the doping area is formed by phosphorus ion implantation.

9. The method as claimed in claim 5, wherein the silicon-rich oxide layer is formed by plasma chemical vapor deposition.

10. The method as claimed in claim 9, wherein the plasma chemical vapor deposition uses Tetraethylor-thosilicate (TOES) as precursor.

11. The method as claimed in claim 9, wherein the plasma chemical vapor deposition uses SiH₄ as precursor.

12. The method as claimed in claim 5, wherein the second gate oxide layer is formed by chemical vapor deposition.
